(19) United States
(12) Patent Application Publication
(10) Pub. No.: US 2008/0203511 A1
(43) Pub. Date: Aug. 28, 2008

(54) Sensor-type semiconductor package and method for fabricating the same

(75) Inventors: Chien-Ping Huang, Taichung (TW); Cheng-Yi Chang, Taichung (TW); Chang-Yueh Chan, Taichung (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/072,369

(22) Filed: Feb. 26, 2008

(30) Foreign Application Priority Data
Feb. 26, 2007 (TW) 096106355
Jul. 12, 2007 (TW) 096125351

(51) Int. Cl. H01L 31/0224; H01L 21/60

(52) U.S. Cl. 257/434; 438/64; 257/E31.124; 257/E21.512

(57) ABSTRACT

The present invention provides a sensor-type semiconductor package and a method for fabricating the same. The method includes the steps of: providing a wafer having a plurality of sensor chips for mounting the wafer on a carrier board having an insulation layer, a plurality of conductive traces, and a substrate; forming a plurality of grooves among the solder pads on the active surfaces of the adjacent sensor chips, so as to expose the conductive traces and form a metal layer in the grooves, to electrically connect to the solder pads on the active surfaces of the adjacent sensor chips and the conductive traces; disposing a transparent medium on the wafer to cover the sensing areas of the sensor chips; removing the substrate, so as to expose the conductive traces and the insulation layer; and cutting the sensor chips along the borders to form a plurality of sensor-type semiconductor packages. This can avoid the formation of slanted grooves on the non-active surface on the wafer and shift in position of the grooves due to failure to align with the cutting lines among the sensor chips, as observed in prior art. Consequently, the problems such as stress concentration and cracking are likely to occur in the contact points of the traces formed in the slanted grooves and the traces in the active surfaces.

### BACKGROUND OF THE INVENTION

1. Field of the Invention

The present invention relates to sensor-type semiconductor packages and methods for fabricating the same, and more particularly, to a wafer-level packaged sensor-type semiconductor package and a method for fabricating the same.

2. Description of the Prior Art

U.S. Pat. Nos. 6,384,472 and 6,509,636, disclose conventional image sensor packages. In the disclosure, a sensor chip is mounted on a chip carrier, and the sensor chip is electrically connected to the chip carrier via bonding wires. Then, a glass is placed on the top of the sensor chip to cover the upper surface of the chip, thereby allowing image lights to be captured by the sensor chip. Afterwards, in a system factory, the fully packaged image sensor package is integrated into an external device such as a printed circuit board (PCB), for applications in various types of electronic products such as digital still cameras (DSC), digital video cameras (DV), optical mice, cellular phones, and so on.

Owing to the ever-increasing information transmission capacity and the growing trend of miniaturization and portability of electronic products, more efforts are put on high input/output (I/O), high heat dissipation and scaled-down integrated circuits, and consequently, the integrated circuits are packaged in a way to achieve high electrical performance and miniaturization. Therefore, the industry gradually developes a wafer-level packaged sensor-type semiconductor package, which is directly packaged on a wafer to facilitate direct electrical connection of a sensor chip to an external device, to allow the wafer-level packaged sensor-type semiconductor package to be effectively applied to small-sized electronic products.

Referring to FIGS. 1A to 1E, FIGS. 1A to 1E are perspective diagrams showing a wafer-level packaged sensor-type semiconductor package and a method for fabricating the same disclosed in U.S. Pat. No. 6,646,289. The method for fabricating the sensor-type semiconductor package includes the steps of: providing a wafer 100 having a plurality of sensor chips 10, and a plurality of extension traces 12 are formed among the solder pads 11 disposed on the adjacent sensor chips 10 (as shown in FIG. 1A); adhering a glass 13 to the wafer 100 through an adhesive layer 14 (as shown in FIG. 1B); thinning the wafer 100 and adhering a cover layer 15 to the back of the thinned wafer 100, and then forming in positions corresponding to the adjacent sensor chips 10 a plurality of slanted grooves 16 penetrating the cover layer 15, the sensor chips 10, and the extension traces 12 to slightly cut in the glass 13 by, for example, etching (as shown in FIG. 1C); forming a plurality of routing traces 17 on the slanted grooves 16 and a portion of the adjacent cover layer 15, and allowing the routing traces 17 to be electrically connected to the extension traces 12 (as shown in FIG. 1D); implanting a plurality of solder balls 18 on the routing traces 17 on the cover layer 15, and cutting the the sensor chips 10 along the borders to obtain a plurality of wafer-level packaged sensor-type semiconductor packages (as shown in FIG. 1E). Similar technical features are disclosed in U.S. Pat. No. 6,777,767.

Referring also to FIG. 2A, owing to the slanted grooves formed on the back of the wafer, in the above-mentioned sensor-type semiconductor package, the sides of the sensor semiconductor package are at slant angles, that is, the longitudinal section of the sensor-type semiconductor package is an inverted trapezoid (planar width progressively decreases from the top to the bottom). The routing traces formed at the sides of the sensor-type semiconductor package are at acute angles with the extension traces formed among solder pads on top surface of the chips, which may easily leads to stress concentration that causes cracks in contact points (as indicated by a crack ‘C′’ in FIG. 2A). Moreover, because the grooves are formed slantingly on the back of the wafer during fabrication, it is not easy to align with the cutting lines among the sensor chips such that the positions of the slanted grooves are shifted by a distance S from the original cutting lines. This will cause the section ‘the slanted grooves to the extension traces’ to deviate in their positions, and subsequently cause the extension traces to deviate in the positions used to electrically connect to the routing traces. Consequently, the routing traces and the extension traces cannot be correctly and effectively connected, and this may damage the chips.

Furthermore, as shown in FIG. 2B, since the sensing area of the central position of each of the sensor chips is not disposed with an adhesive layer for mounting the glass during the above-mentioned thinning process of the wafer, the sensing area is unoccupied. Consequently, the chips are likely to crack (as indicated by a crack C′ shown in FIG. 2B) due to stress induced by polishing.

Accordingly, it is important to develop a wafer-level packaged sensor-type semiconductor package and a method for fabricating the same, which can avoid the problems such as cracking of traces, poor electrical connection of the traces caused by errors in aligning with cutting lines during the formation of grooves on the back of a wafer, and damage to chips during the thinning process in prior art.

### SUMMARY OF THE INVENTION

In light of the shortcomings of the above prior arts, it is an object of the present invention to provide a sensor-type semiconductor package and a method for fabricating the same, which can avoid the problems such as stress concentration and cracking in the contact points of traces caused by acute angles formed at the contact points of the traces.

It is another object of the present invention to provide a sensor-type semiconductor package and a method for fabricating the same, which can avoid the problems such as poor electrical connection of traces and damages to the chip caused by aligning errors when forming grooves on the back of the wafer according to prior art.

It is a further object of the present invention to provide a sensor-type semiconductor package and a method for fabricating the same, which can avoid the problems such as damages to the chip when its sensing area is unoccupied during thinning process according to prior art.

To achieve the above-mentioned and other objects, the method for fabricating the sensor-type semiconductor package of the present invention includes the steps of: providing a wafer having a plurality of sensor chips and a carrier board, wherein the wafer and each of the sensor chips has an active surface and a non-active surface opposed thereto, a sensing area and a plurality of solder pads are disposed on the active surface of each of the sensor chips, and the carrier board has a substrate, a plurality of conductive traces disposed on the substrate, and an insulation layer covering the substrate and the conductive traces, such that the wafer is mounted on the insulation layer of the carrier board; forming a plurality of grooves among the solder pads on the active surfaces of the adjacent sensor chips, the depths of the grooves stop at the positions of the conductive traces; forming a metal layer in the grooves, and electrically connect the metal layer to the solder pads of the sensor chips and the conductive traces of the carrier board; disposing a transparent medium on the wafer to cover the sensing areas; removing the substrate of the carrier board, so as to expose the conductive traces and the insulation layer; and cutting the sensor chips along the borders to form a plurality of sensor-type semiconductor packages.

The present invention further discloses a method for fabricating the carrier board, including the steps of: providing a substrate; forming a resist on the substrate, and forming a plurality of openings in the resist to expose the substrate; electroplating the conductive traces into the openings; removing the resist; and forming an insulation layer on the substrate to cover the conductive traces and the substrate.

Moreover, after removing the substrate, a solder mask may be further formed on the insulation layer, and a plurality of openings are formed on the solder mask to expose the conductive traces, so as to receive a plurality of electrical conduction elements. Then, the sensor chips are cut along the borders to form a plurality of sensor-type semiconductor packages.

Additionally, to increase adhesion and insulation between the metal layer and the sensor chips, after a plurality of grooves (the depths of the grooves stop at the positions of the conductive traces of the carrier board) are formed among the solder pads on the active surfaces of the adjacent sensor chips, insulation fillers may be filled in the grooves. Then, a plurality of openings are formed in the insulation fillers. A metal layer is formed in the openings, and the metal layer is electrically connected to the solder pads of the sensor chips and the conductive traces of the carrier board. Subsequently, a transparent medium is disposed on the wafer to cover the sensing areas. The substrate of the carrier board is removed so that the conductive wires and the insulation layer are exposed. The sensor chips are cut along the borders to form a plurality of sensor-type semiconductor packages. The insulation fillers may be made of, for example, polyimide (PI).

By the above-mentioned fabrication method, the present invention further discloses a sensor-type semiconductor package, including: an insulation layer having a top surface and a bottom surface opposed thereto; a plurality of conductive traces formed at the periphery of the bottom surface of the insulation layer; a sensor chip having an active surface and an non-active surface opposed thereto, the sensor chip is disposed on the top surface of the insulation layer via its non-active surface, and a sensing area and a plurality of solder pads are formed on the active surface; a metal layer disposed on the sides of the sensor chip and the insulation layer to electrically connect to the solder pads of the sensor chip and the conductive traces; and a transparent medium formed on the active surface of the sensor chip to cover the sensing area.

Furthermore, insulation fillers are formed between the sides of the metal layer and the sensor chip, thereby increasing adhesion and insulation between the metal layer and the sensor chip.

Accordingly, the sensor-type semiconductor package and a method fabricating the same of the present invention provides a wafer having a plurality of sensor chips, wherein the wafer may be thinned before being mounted on a carrier board having an insulation layer, a plurality of conductive traces, and a substrate; forming a plurality of grooves among the solder pads on active surfaces of the adjacent sensor chips to expose the conductive traces; forming a metal layer in the grooves to electrical connect to the solder pads on the active surfaces of the adjacent sensor chips and the conductive traces; disposing a transparent medium on the wafer to cover the sensing areas; removing the substrate of the carrier board to expose the conductive traces and the insulation layer; and cutting the sensor chips along the borders to form a plurality of wafer-level sensor-type semiconductor packages. By the above-mentioned process, the drawbacks of the prior art, such as poor electrical connection in traces and damage to chips caused by shift in the positions of grooves when failure to align to cutting lines occurs during formation of the grooves on the back of the wafer, and cracking caused by stress concentration, which occurs when the contact points of the sides of the sensor chips and the traces on the active surfaces are at acute angles (as is the case when the sides of the semiconductor package are at a slant angles), can be avoided at the same time. Moreover, since the present invention provides a wafer thinned before being mounted on a carrier board for fabrication, the structural integrity of the wafer is strengthened during fabrication. Therefore, cracking induced by polishing during the conventional thinning process may be avoided.

### BRIEF DESCRIPTION OF THE DRAWINGS

FIGS. 1A to 1E are perspective diagrams showing the wafer-level packaged sensor-type semiconductor package and the method for fabricating the same according to U.S. Pat. No. 6,646,289;

FIG. 2A is a perspective diagram showing a shift in position of a groove during the formation of a groove during fabrication of a sensor-type semiconductor package according to prior art;

FIG. 2B is a perspective diagram showing a cracked chip during polishing of the back of a wafer during fabrication of a sensor-type semiconductor package according to prior art;

FIGS. 3A to 3K are perspective diagrams showing the sensor-type semiconductor package and the method for fabricating the same according to the first embodiment of the present invention;

FIG. 4 is a perspective diagram showing the sensor-type semiconductor package and the method for fabricating the same according to the second embodiment of the present invention; and

FIGS. 5A to 5G are perspective diagrams showing the sensor-type semiconductor package and the method for fabricating the same according to the third embodiment of the present invention

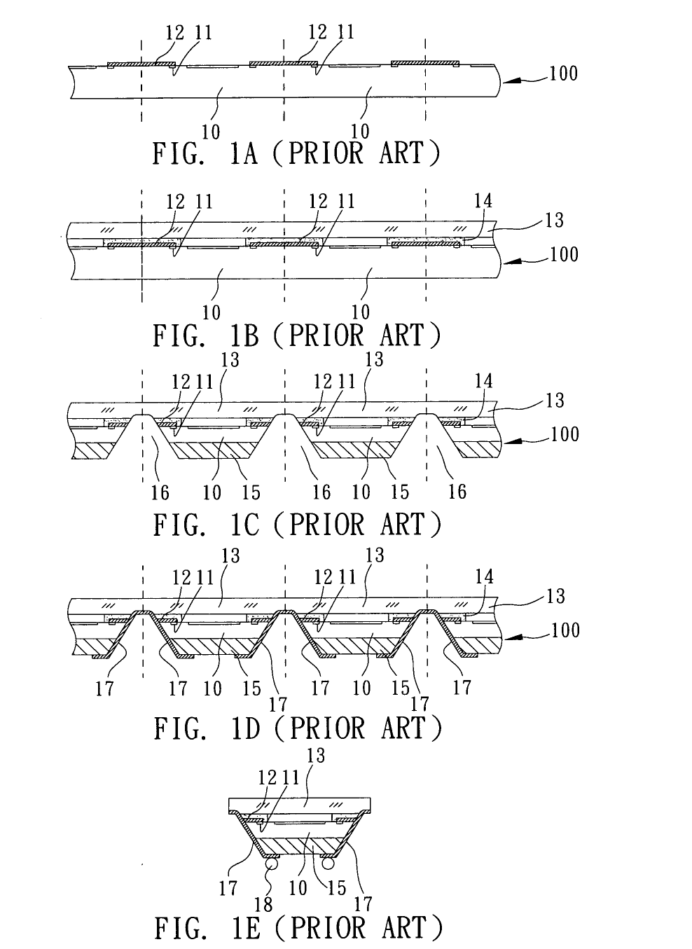

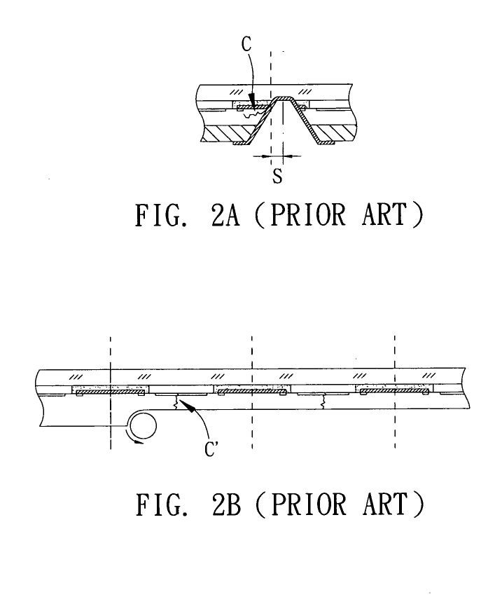

### DETAILED DESCRIPTION OF THE PREFERRED EMBODIMENTS

### First Embodiment

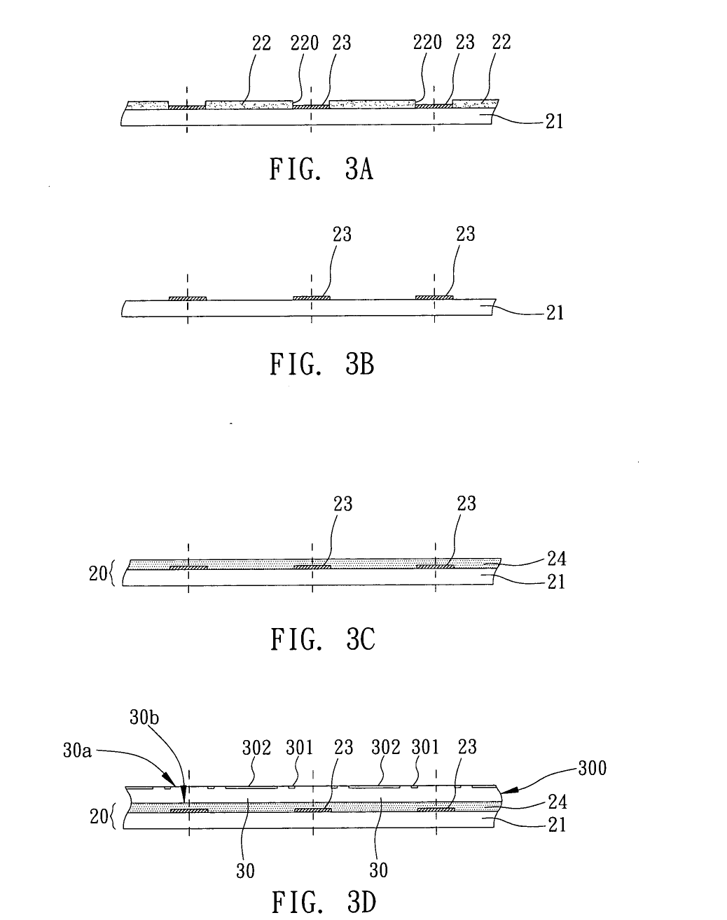

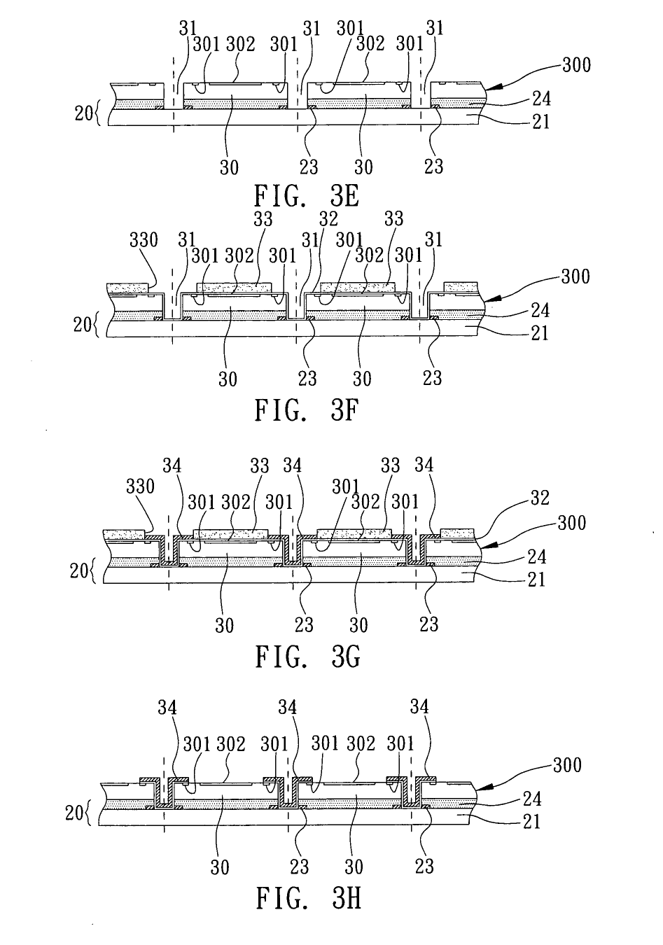

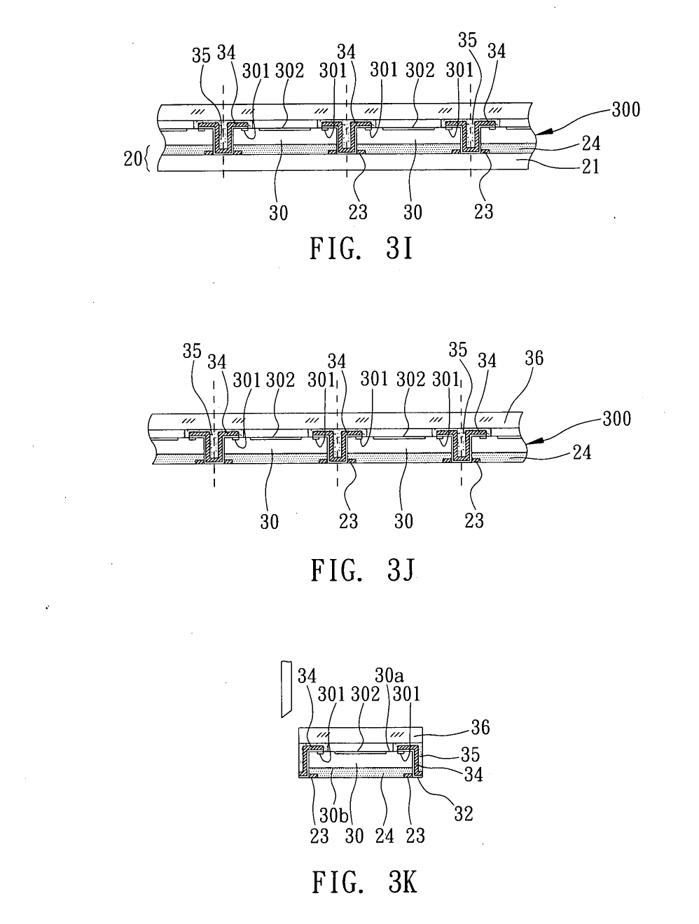

Referring to FIGS. 3A to 3K, FIGS. 3A and 3K are perspective diagrams showing the sensor-type semiconductor package and the method for fabricating the same according to the first embodiment of the present invention.

As shown in FIGS. 3A to 3C, a substrate 21 made of a metal, such as copper, is provided. A resist 22 is formed on the metal substrate 21, and a plurality of openings 220 are formed on the resist 22 to expose the metal substrate 21. A plurality of conductive traces 23, such as Au/Pd/Ni, are electroplated into the openings 220. Then, the resist 22 is removed. An insulation layer 24 is formed on the substrate 21 to cover the conductive traces 23 and the substrate 21. The insulation layer 24 may be made of B-stage epoxy or polyimide, and is 5˜30 μm thick.

By the above-mentioned steps, a carrier board 20 having the substrate 21, the conductive traces 23 disposed on the substrate 21, and the insulation layer 24 covering the substrate 21 and conductive traces 23 is formed.

As shown in FIG. 3D, a wafer 300 including a plurality of sensor chips 30 is provided. The wafer 300 and sensor chips 30 each has an active surface 30a and a non-active surface 30b opposed thereto. A sensing area 302 and a plurality of solder pads 301 are disposed on the active surface 30a of each of the sensor chips 30, thereby allowing the wafer 300 to be mounted on the insulation layer 24 of the carrier board 20. The wafer 300 is processed beforehand by a thinning process such as polishing, so that the wafer 300 is 50˜150 μm thick.

As shown in FIG. 3E, a plurality of grooves 31 are formed among the solder pads 301 on the active surfaces 30a of the adjacent sensor chips 30, and the depths of the grooves 31 stop at the positions of the conductive traces 23. In this embodiment, the grooves 31 may be U-shaped, V-shaped, or Y-shaped.

As shown in FIG. 3F, a conductive layer 32 is formed on the active surfaces 30a of the wafer and the surfaces of the grooves 31 by sputtering or vaporization. The conductive layer 32 is an under-bump metallization (UBM) layer, and may be made of titanium/copper/nickel (Ti/Cu/Ni), titanium tungsten/gold (TiW/Au), aluminum/nickel vanadium/copper (Al/NiV/Cu), titanium/nickel vanadium/copper (Ti/NiV/Cu), titanium tungsten/nickel (TiW/Ni), titanium/copper/copper (Ti/Cu/Cu), or titanium/copper/copper/nickel (Ti/Cu/Cu/Ni).

Then, a resist 33 is formed on the conductive layer 32, and a plurality of openings 330 on the resist 33 are formed to correspond to the grooves 31.

As shown in FIG. 3G, a metal layer 34, such as a copper layer, is electroplated into the openings 330, and the metal layer 34 is electrically connected to the solder pads 301 of the adjacent sensor chips 30 and the conductive traces 23 of the carrier board 20. The metal layer 34 is 2˜5 μm thick.

As shown in FIG. 3H, the resist 33 and the conductive layer 32 below the resist 33 are removed.

As shown in FIG. 3I, a transparent medium 36 is disposed on the wafer 300 to cover the sensing area 302. The transparent medium 36 may be, for example, glass, and is adhered to the wafer 300 through an adhesive layer 35, which is adhered to the periphery of the sensor chips 30 and covers the metal layer 34 (but not the sensing areas 302 of the sensor chips 30). The transparent medium 36 covers the sensing areas 302 of the sensor chips 30.

Also shown in FIG. 3J, the substrate 21 of the carrier board 20 is removed, so as to expose the conductive traces 23 and insulation layer 24. The substrate 21 may be, for example, a copper substrate, which can be removed by etching.

As shown in FIG. 3K, the sensor chips 30 are cut along the borders to form a plurality of wafer-level sensor-type semiconductor packages.

By the above-mentioned fabrication method, the present invention further discloses a sensor-type semiconductor package, includes an insulation layer 24, a plurality of conductive traces 23, a plurality of sensor chips 30, a conductive layer 32, a metal layer 34, and a transparent medium 36. The insulation layer 24 has a top surface and a bottom surface opposed thereto. The conductive traces 23 are formed at the periphery of the bottom surface of the insulation layer 24, and the surfaces of the conductive traces 23 are level with the bottom surface of the insulation layer 24. The sensor chips 30 each has an active surface 30a and a non-active surface 30b opposed thereto, and each of the sensor chips 30 is disposed on the top surface of the insulation layer 24 through the inactive surface 30b, and a sensing area 302 and a plurality of solder pads 301 are formed on the active surface 30a. The metal layer 34 is disposed on the sides of the sensor chips 30 and the insulation layer 24, and the metal layer 34 is electrically connected to the solder pads 301 of the sensor chips 30 and the conductive traces 23 at the bottom surface of the insulation layer 24. The transparent medium 36 is formed on the active surfaces 30a of the sensor chips 30 to cover the sensing area 302. Additionally, the conductive layer 32 is formed between the metal layer 34 and the sensor chips 30. The conductive layer 32 is an under-bump metallization (UBM) layer.

Accordingly, the sensor-type semiconductor package and a method fabricating the same of the present invention provides a wafer having a plurality of sensor chips, wherein the wafer may be thinned before being mounted on a carrier board having an insulation layer, a plurality of conductive traces, and a substrate; forming a plurality of grooves among the solder pads on active surfaces of the adjacent sensor chips to expose the conductive traces; forming a metal layer in the grooves to electrical connect to the solder pads on the active surfaces of the adjacent sensor chips and the conductive traces; disposing a transparent medium on the wafer to cover the sensing areas; removing the substrate of the carrier board to expose the conductive traces and the insulation layer; and cutting the sensor chips along the borders to form a plurality of wafer-level sensor-type semiconductor packages. By the above-mentioned process, the drawbacks of the prior art, such as poor electrical connection in traces and damage to chips caused by shift in the positions of grooves when failure to align to cutting lines occurs during formation of the grooves on the back of the wafer, and cracking caused by stress concentration, which occurs when the contact points of the sides of the sensor chips and the traces on the active surfaces are at acute angles (as is the case when the sides of the semiconductor package are at a slant angles), can be avoided at the same time. Moreover, since the present invention provides a wafer thinned before being mounted on a carrier board for fabrication, the structural integrity of the wafer is strengthened during fabrication. Therefore, cracking induced by polishing during the conventional thinning process may be avoided.

### Second Embodiment

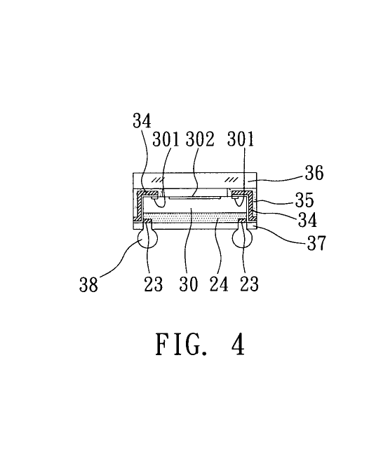

Referring to FIG. 4, FIG. 4 is a perspective diagram showing the sensor-type semiconductor package and the method for fabricating the same according to the second embodiment of the present invention. For brevity, identical or similar parts and components with the FIG. 3 are represented by the same reference numerals.

The sensor-type semiconductor package and the method for fabricating the same according to the second embodiment differ from those according to the first embodiment in that after removing the substrate of the carrier board, a solder mask 37 may be further formed on the insulation layer 24 and a plurality of openings are formed on the solder mask 37, so as to expose the conductive traces 23. This will allow implantation of a plurality of electrical conduction elements 38, such as solder balls. The sensor chips are cut along the borders to form a plurality of sensor-type semiconductor chips.

### Third Embodiment

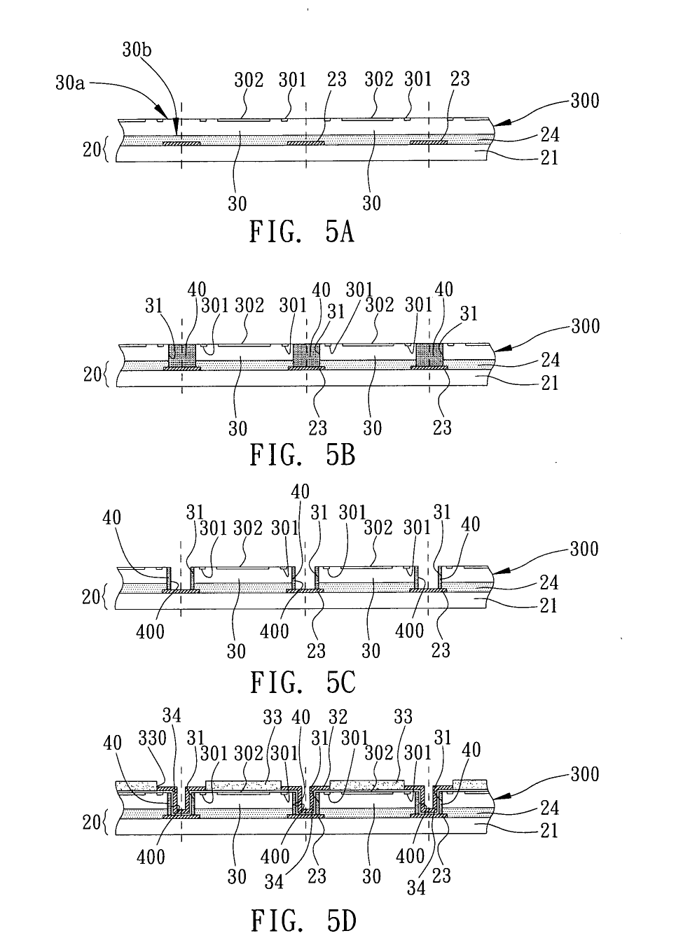

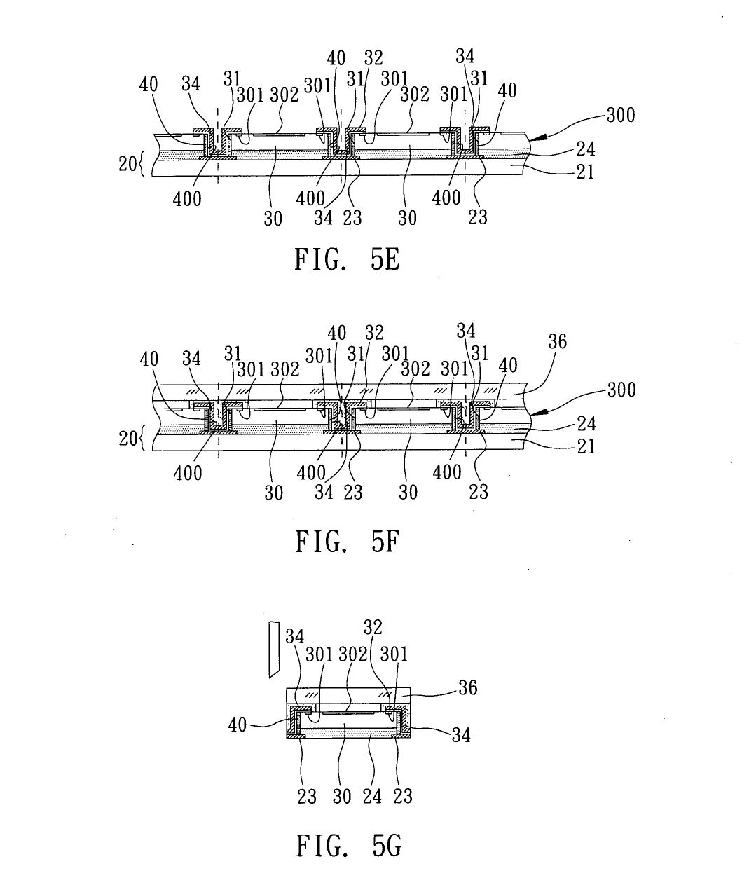

Referring to FIGS. 5A to 5G, FIGS. 5A and 5G are perspective diagrams showing the sensor-type semiconductor package and the method for fabricating the same according to the third embodiment of the present invention.

The sensor-type semiconductor package and the method for fabricating the same according to the embodiment differ from those of the second embodiment is that the insulation fillers are formed between the sides of metal layer and the sensor chips, so as to increase adhesion and insulation between the metal layer and sensor chip.

As shown in FIG. 5A, a wafer 300 having a plurality of sensor chips 30 and a carrier board 20 is provided. The wafer 300 and sensor chips 30 each has an active surface 30a and a non-active surface 30b opposed thereto. The carrier board 20 has a substrate 21, a plurality of conductive traces 23 disposed on the substrate 21, and an insulation layer 24 covering the substrate 21 and the conductive traces 23, so as to mount the wafer 300 on the insulation layer 24 of the carrier board 20.

As shown in FIG. 5B, a plurality of grooves 31 are formed among the solder pads 301 on the active surfaces 30a of the adjacent sensor chips 30, and the depths of the grooves 31 stop at the positions of the conductive traces 23. Insulation fillers 40, such as polyimide, are filled in the grooves 31.

As shown in FIG. 5C, a plurality of openings 400 are formed in the insulation fillers 40 by etching or cutting. The widths of the openings 400 are smaller than the widths of the grooves 31, so that a portion of the insulation fillers 40 still covers the sides of the sensor chips and the conductive traces 23 are exposed in the openings 400.

As shown in FIG. 5D, a conductive layer 32 is formed on the active surface 30a of the wafer 300 and the surfaces of the insulation fillers 40. A resist 33 is formed on the conductive layer 32, and a plurality of openings 330 are formed on the resist 33 to correspond to the grooves 31.

Then, a metal layer 34 is formed in the openings 300 by electroplating. The metal layer 34 is filled to the openings of 400, and is electrically connected to the conductive traces 23 and the solder pads 301 on the active surfaces of the adjacent sensor chips 30. The insulation fillers 40 and the conductive layer 32 are disposed between the metal layer 34 and the adjacent sensor chips 30. Since the sides of the sensor chips 30 are still covered with the insulation fillers 40, adhesion and insulation between the metal layer 34 and the sensor chips 20 can be increased by the insulation fillers 40.

As shown in FIG. 5E, the resist 33 and the conductive layer 32 below the resist 33 are removed.

Also shown in FIG. 5F, a transparent medium 36 is disposed on the wafer 300 to cover the sensing area 302. The substrate 21 of the carrier board 20 is removed, so as to expose the conductive traces 23 and the insulation layer 24.

As shown in FIG. 5G, the sensor chips 30 are cut along the borders to provide a plurality of sensor-type semiconductor packages.

The present invention has been described using exemplary preferred embodiments. However, it is to be understood that the scope of the present invention is not limited to the disclosed arrangements. The scope of the claims, therefore, should be accorded the broadest interpretation, so as to encompass all such modifications and similar arrangements.

What is claimed is:

1. A fabricating method for fabricating a sensor-type semiconductor package, comprising the steps of:
providing a wafer having a plurality of sensor chips and a carrier board, the wafer and each of the sensor chips having an active surface and a non-active surface opposed thereto, a sensing area and a plurality of solder pads being disposed on the active surface of each of the sensor chips, and the carrier board having a substrate, a plurality of conductive traces disposed on the substrate, and an insulation layer covering the substrate and the conductive traces, so as to mount the wafer on the insulation layer of the carrier board;
forming a plurality of grooves among the solder pads on the active surfaces of the sensor chips, and the depths of the grooves stopping at the positions of the conductive traces;
forming a metal layer in the grooves, and the metal player being electrically connected to the solder pads on the sensor chips and the conductive traces of the carrier board;
disposing a transparent medium on the wafer to cover the sensing areas;
removing the substrate of the carrier board, so as to expose the conductive traces and insulation layer; and
cutting the sensor chips along their borders to form a plurality of sensor-type semiconductor packages.

2. The fabricating method of claim 1, wherein a method for fabricating the carrier board comprises the steps of:
providing a substrate;
forming a resist on the substrate, and forming a plurality of openings in the resist to expose the substrate;
electroplating the conductive traces into the openings;
removing the resist; and
forming an insulation layer on the substrate to cover the conductive traces and the substrate.

3. The fabricating method of claim 1, wherein the insulation layer is made of one of B-stage epoxy and polyimide.

4. The fabricating method of claim 1, wherein the wafer is thinned before being mounted on the carrier board.

5. The fabricating method of claim 1, wherein each of the grooves is one selected from the group consisting of an U-shaped groove, a V-shaped groove, and a Y-shaped groove.

6. The fabricating method of claim 1, wherein a method for fabricating the metal layer comprises the steps of:
forming a conductive layer on the active surface of the wafer and the surfaces of the grooves;
forming a resist on the conductive layer, and forming a plurality of openings in the conductive layer to correspond to the grooves;
forming the metal layer in the openings of the resist, and the metal layer being electrically connected to the solder pads of the sensor chips and the conductive traces of the carrier board; and
removing the resist and the conductive layer below the resist.

7. The fabricating method of claim 6, wherein the conductive layer is an under-bump metallization (UBM) layer formed by sputtering or vaporizing, and is made of one selected from the group consisting of titanium/copper/nickel (Ti/Cu/Ni), titanium tungsten/gold (TiW/Au), aluminum/nickel vanadium/copper (Al/NiV/Cu), titanium/nickel vanadium/copper (Ti/NiV/Cu), titanium tungsten/nickel (TiW/Ni), titanium/copper/copper (Ti/Cu/Cu), and titanium/copper/copper/nickel (Ti/Cu/Cu/Ni).

8. The fabricating method of claim 1, wherein the transparent medium is disposed on the wafer through an adhesive layer adhered to the periphery of the sensor chips, and the adhesive layer covers the metal layer but not the sensing areas of the sensor chips, such that the transparent medium covers the sensing areas of the sensor chips.

9. The fabricating method of claim 1, wherein after the substrate is removed, a solder mask is formed on the insulation layer, and a plurality of openings are formed on the solder mask, so as to expose the conductive traces to receive a plurality of electrical conduction elements, and the sensor chips are cut along the borders to form a plurality of sensor-type semiconductor packages.

10. The fabricating method of claim 1, wherein the method for fabricating the metal layer comprises:
filling a plurality of insulation fillers in the grooves of the wafer;
forming a plurality of openings in the insulation fillers, so as to expose the conductive traces;
forming a conductive layer on the active surface of the wafer and the surfaces of the insulation fillers;
forming a resist on the conductive layer, and forming a plurality of openings in the resist to correspond to the grooves;
electroplating the metal layer into the openings on the resist, forming the metal layer in the openings of the insulation fillers, and electrically connecting the metal layer to the conductive traces and the solder pads on the active surfaces of the sensor chips; and
removing the resist and the conductive layer below the resist.

11. The fabricating method of claim 10, wherein the insulation fillers are made of polyimide.

12. The fabricating method of claim 10, wherein the widths of the openings of the insulation fillers are smaller than the widths of the grooves, so that a portion of the insulation fillers covers the sides of the sensor chips.

13. A sensor-type semiconductor package, comprising:
an insulation layer having a top surface and a bottom surface opposed thereto;
a plurality of conductive traces disposed at the periphery of the bottom surface of
the insulation layer;
a sensor chip having an active surface and a non-active surface opposed thereto, the non-active surface being disposed on the top surface of the insulation layer, and a sensing area and a plurality of solder pads being formed on the active surface;
a metal layer disposed on the sides of the sensor chip and the insulation layer, the metal layer being electrically connected to the solder pads of the sensor chip and the conductive traces at the bottom surface of the insulation layer; and
a transparent medium formed on the active surface of the sensor chip to cover the sensing area.

14. The sensor-type semiconductor package of claim 13, wherein the surface of the conductive traces are level with the bottom surface of the insulation layer.

15. The sensor-type semiconductor package of claim 13, wherein the insulation layer is made of one of B-stage epoxy and polyimide.

16. The sensor-type semiconductor package of claim 13, wherein the wafer is thinned.

17. The sensor-type semiconductor package of claim 13, wherein each of the grooves is one selected from the group consisting of an U-shaped groove, a V-shaped groove, and a Y-shaped groove.

18. The sensor-type semiconductor package of claim 13, wherein a conductive layer is further formed between the metal layer and the sensor chip.

19. The sensor-type semiconductor package of claim 18, wherein the conductive layer is an under-bump metallization (UBM) layer made of one selected from the group consisting of titanium/copper/nickel (Ti/Cu/Ni), titanium tungsten/gold (TiW/Au), aluminum/nickel vanadium/copper (Al/NiV/Cu), titanium/nickel vanadium/copper (Ti/NiV/Cu), titanium tungsten/nickel (TiW/Ni), titanium/copper/copper (Ti/Cu/Cu), and titanium/copper/copper/nickel (Ti/Cu/Cu/Ni).

20. The sensor-type semiconductor package of claim 13, wherein the transparent medium is adhered to the wafer through an adhesive layer adhered to the periphery of the sensor chip, and the adhesive layer covers the metal layer but not the sensing areas of the sensor chip, such that the transparent medium covers the sensing areas of the sensor chip.

21. The sensor-type semiconductor package of claim 13, wherein a solder mask is further formed on the insulation layer, and a plurality of openings are formed in the solder mask to expose the conductive traces and receive a plurality of electrical conduction elements.

22. The sensor-type semiconductor package of claim 13, wherein a plurality of insulation fillers are further formed between the metal layer and the sensor chip.

23. The sensor-type semiconductor package of claim 22, wherein the insulation fillers are made of polyimide.
